(19) United States
(12) Patent Application Publication
(10) Pub. No.: US 2015/0188005 A1
(43) Pub. Date: Jul. 2, 2015

(54) LIGHT EMITTING DIODE PACKAGE AND METHOD OF MANUFACTURING SAME

(71) Applicant: ADVANCED OPTOELECTRONIC TECHNOLOGY, INC., Hsinchu Hsien 303 (TW)

(72) Inventors: Chao-Hsiung CHANG, Hukou (TW); Pin-Chuan CHEN, Hukou (TW); Hou-Te LIN, Hukou (TW); Lung-Hsin CHEN, Hukou (TW); Wen-Liang TSENG, Hukou (TW)

(21) Appl. No.: 14/526,797

(22) Filed: Oct. 29, 2014

(30) Foreign Application Priority Data
Dec. 30, 2013 (CN) 201310742364.2

(51) Int. Cl. H01L 33/52; H01L 33/08; H01L 33/62

(52) U.S. Cl. CPC H01L 33/52; H01L 33/62; H01L 33/08; H01L 2933/005; H01L 2933/0066; H01L 2933/0033

(57) ABSTRACT

A method for packaging an light emitting diode, includes: arranging one or more light emitting diode dies on a film; encapsulating the one or more light emitting diode dies on the film; removing the film from the one or more encapsulated light emitting diode dies to expose a surface of the one or more encapsulated light emitting diode dies; forming an isolating layer on the exposed surface encapsulation surface portion of the one or more encapsulated light emitting diode dies so as to define a plurality of recesses; and forming a plurality of leads in the plurality of recesses of the one or more encapsulated light emitting diode dies, with each one of the plurality of leads being connected to one of the un-encapsulated electrodes of the one or more light emitting diode dies.

### CROSS-REFERENCE TO RELATED APPLICATIONS

This application claims priority to Chinese patent application no. 201310742364.2 filight emitting diode on Dec. 30, 2013, the contents of which are incorporated by reference herein.

### FIELD

The present disclosure generally relates to a light emitting diode (light emitting diode) package and method for manufacturing the same.

### BACKGROUND

In recent years, due to excellent light quality and high luminous efficiency, light emitting diodes (light emitting diodes) have increasingly been used as substitutes for incandescent bulbs, compact fluorescent lamps and fluorescent tubes as light sources of illumination devices.

### BRIEF DESCRIPTION OF THE DRAWINGS

Implementations of the present technology will now be described, by way of example only, with reference to the attached figures.

FIG. 1 is a diagrammatic, cross-sectional view of an light emitting diode package in accordance with an exemplary embodiment of the present disclosure.

FIG. 2 is a diagrammatic, bottom view of the light emitting diode package of FIG. 1.

FIG. 3 is a diagrammatic, top view of the light emitting diode package of FIG. 1.

FIG. 4 is a flow chart of a method for forming the light emitting diode package in accordance with the first embodiment of the present disclosure.

FIGS. 5-9 are diagrammatic cross sections showing an light emitting diode package in accordance with the embodiment of the present disclosure processed by various steps of the light emitting diode packaging method of FIG. 4.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

A definition that applies throughout this disclosure will now be presented.

The term “comprising,” when utilized, means “including, but not necessarily limited to”; it specifically indicates open-ended inclusion or membership in the so-described combination, group, series and the like.

The present disclosure is described in relation to a light emitting diode package and method for manufacturing the same.

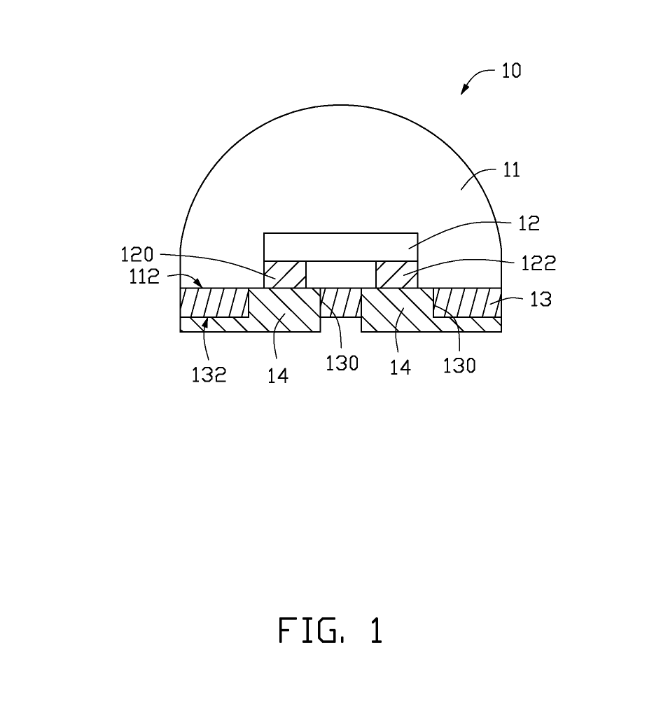

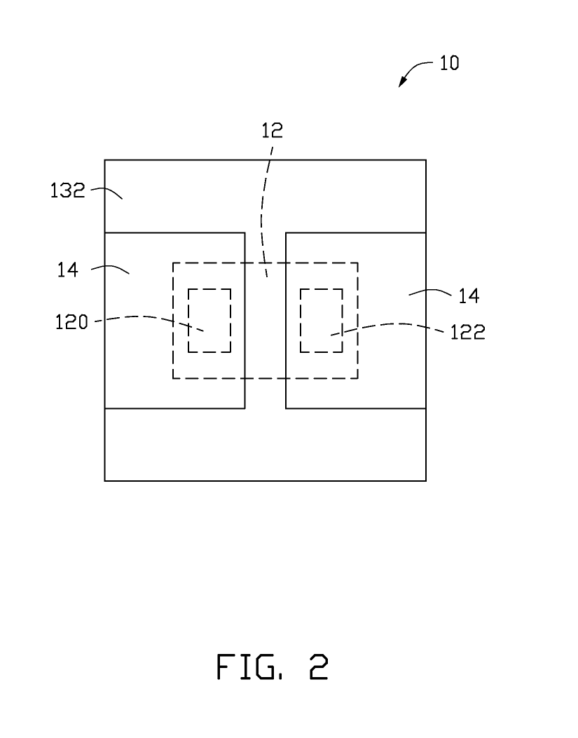

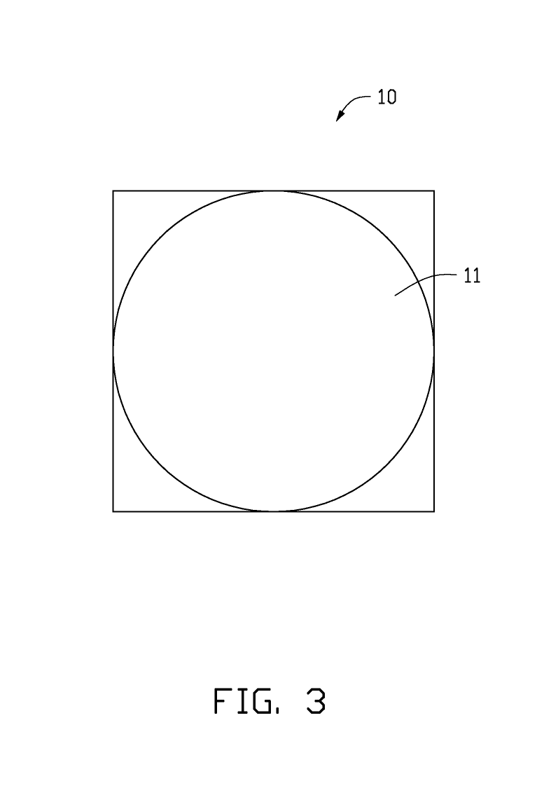

FIGS. 1-3 illustrate that a light emitting diode package 10 includes an encapsulation 11, an light emitting diode die 12, an isolating layer 14, and two leads 15.

The encapsulation 11 can be made of transparent material, such as epoxy resin. Optionally, there can be phosphor powder distributing in the encapsulation 11, so as to obtain light with a requirement color when light radiated from the light emitting diode die 12 is excitated by the phosphor powder to have a different wavelength and then mixture with original light.

The light emitting diode die 12 is mounted on a bottom of the encapsulation 11. the light emitting diode die 12 has two electrodes 120, 122. the two electrodes 120, 122 are exposed out of the bottom of the encapsulation 11. specially, the encapsulation 11 has a bottom surface 112. the two electrodes 120, 122 stand on the bottom surface 112 and are un-encapsulated on the bottom of the encapsulation.

The isolating layer 13 is not transparent. The isolating layer 13 covers the bottom of the encapsulation 11. Further, the isolating layer 13 is attached to the bottom surface 112 of the encapsulation 11 without the electrodes 120, 122 located. Two recesses 130 are defined below the two electrodes 120, 122, respectively, thereby exposing the electrodes 120, 122 out of the isolating layer 13. The isolating layer 13 has a lower surface 132 which is away from the encapsulation 11. In this embodiment, the lower surface 132 is parallel to the bottom surface 112 of the encapsulation 11. The isolating layer 13 can be made of epoxy molding compound (EMC) or sheet molding compound (SMC).

The two leads 14 each are positioned at one of the recesses 130. Each lead 14 is extended from one recess 130 of the isolating layer 13 away from the encapsulation 11 and covers the lower surface 132 of the isolating layer 13. Each lead 14 is attached with a corresponding electrode 120/122, thereby electrically connecting to the light emitting diode die 12.

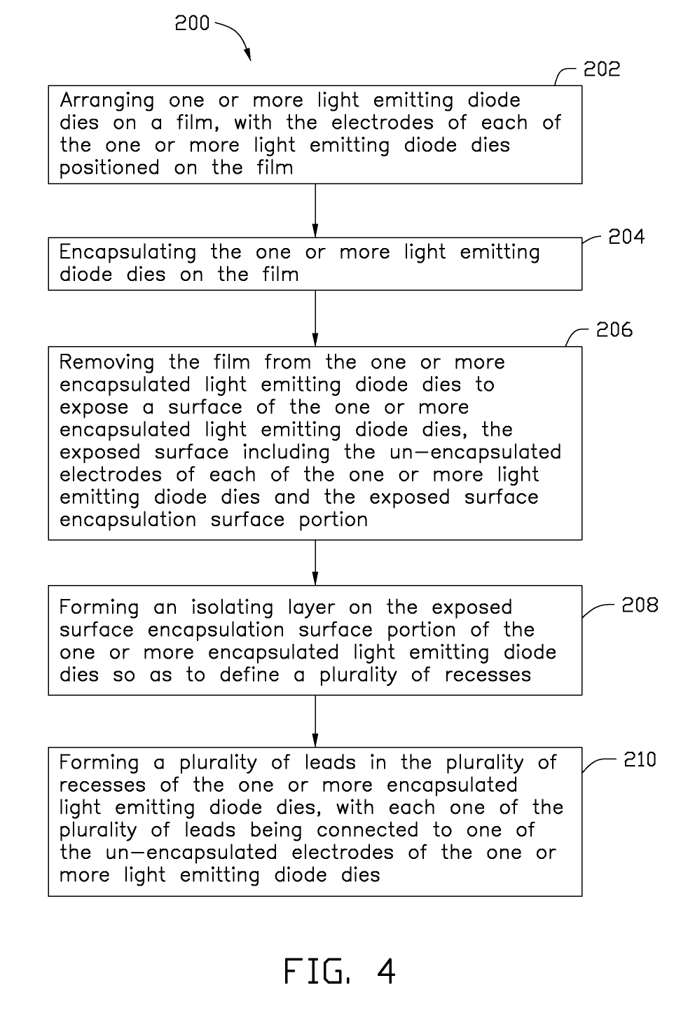

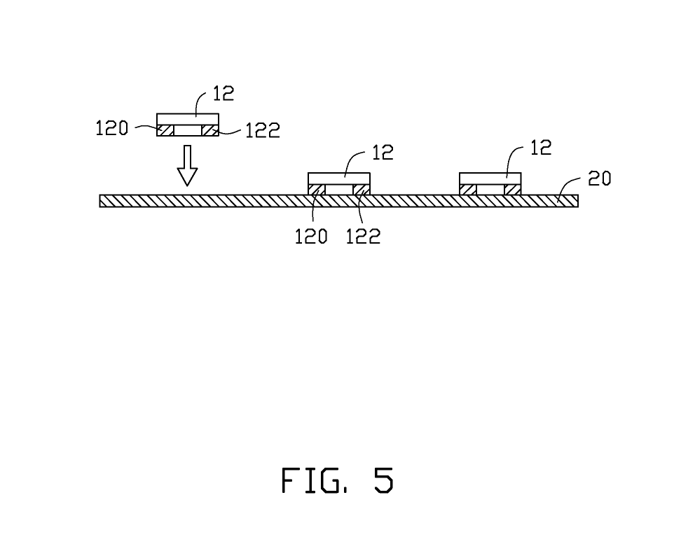

Referring to FIG. 4, a flowchart is presented in accordance with an example embodiment which is being thus illustrated. The example method 200 is provided by way of example, as there are a variety of ways to carry out the method. The method 200 described below can be carried out using the configurations illustrated in FIGS. 5-9, for example, and various elements of these figures are referenced in explaining example method 200. Each block shown in FIG. 4 represents one or more processes, methods or subroutines, carried out in the example method 400. Additionally, the illustrated order of blocks is by example only and the order of the blocks can change according to the present disclosure. The example method 200 can begin at block 202.

A method for manufacturing the light emitting diode package in accordance with the first embodiment of the present disclosure includes steps of:
arranging one or more light emitting diode dies on a film, with the electrodes of each of the one or more light emitting diode dies positioned on the film;
encapsulating the one or more light emitting diode dies on the film;
removing the film from the one or more encapsulated light emitting diode dies to expose a surface of the one or more encapsulated light emitting diode dies, the exposed surface including the un-encapsulated electrodes of each of the one or more light emitting diode dies and the exposed surface encapsulation surface portion;
forming an isolating layer on the exposed surface encapsulation surface portion of the one or more encapsulated light emitting diode dies so as to define a plurality of recesses; and
forming a plurality of leads in the plurality of recesses of the one or more encapsulated light emitting diode dies, with each one of the plurality of leads being connected to one of the un-encapsulated electrodes of the one or more light emitting diode dies.

At block 202, referring to FIG. 5, a film 20 is provided, and one or more light emitting diode dies 12 are arranged on the film 20. Two electrodes 120, 122 of each light emitting diode die 12 are attached on the film 20. In this embodiment, the light emitting diode dies 12 can be inverted by flip-chip bonding, thereby attaching the electrodes 120, 122 on the film 20.

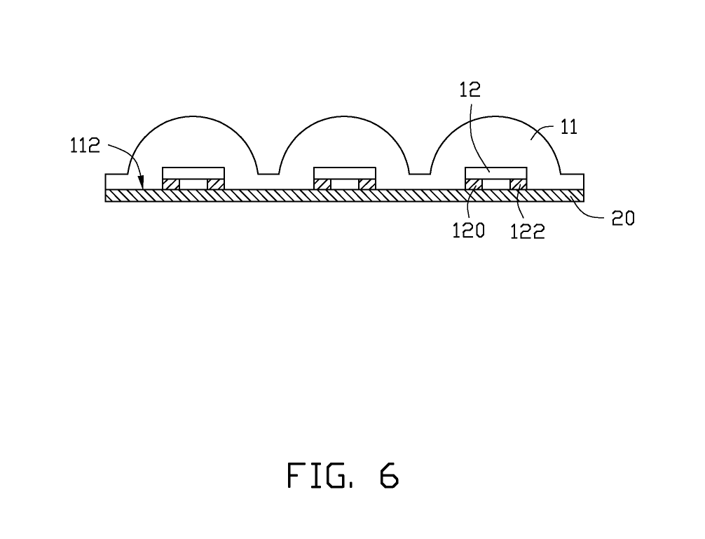

At block 204, referring to FIG. 6, the one or more light emitting diode dies 12 are encapsulated on the film 20. Encapsulating material is formed on the film 20 to cover the light emitting diode dies 12, and then the encapsulating material is solidified to form an encapsulation 11. The two electrodes 120, 122 are inserted in the encapsulation 11 with bottom attached on the film 20. In this embodiment, the encapsulating material can be fillight emitting diode on the film 20 by molding.

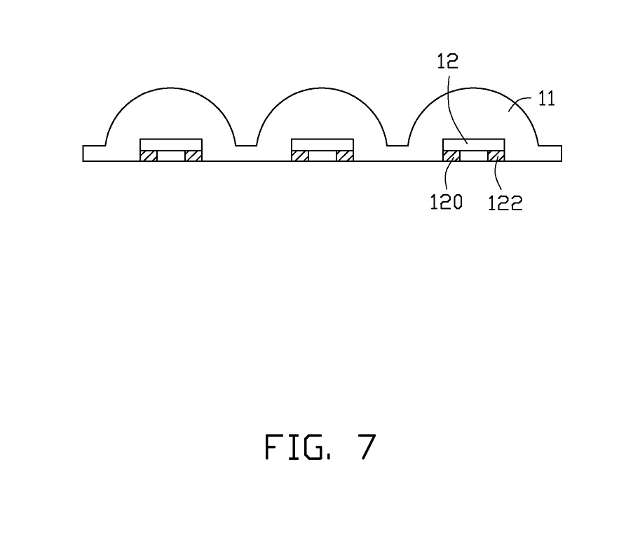

At block 206, referring to FIG. 7 at the same time, the film 20 is removed from the one or more encapsulated light emitting diode dies 12, and a bottom surface 112 of the encapsulation 11 and bottoms of the two electrodes 120, 122 of each light emitting diode dies 12 are exposed outside. The exposed surface includes the un-encapsulated electrodes 120, 122 of each of the one or more light emitting diode dies 12 and the exposed bottom surface encapsulation surface portion.

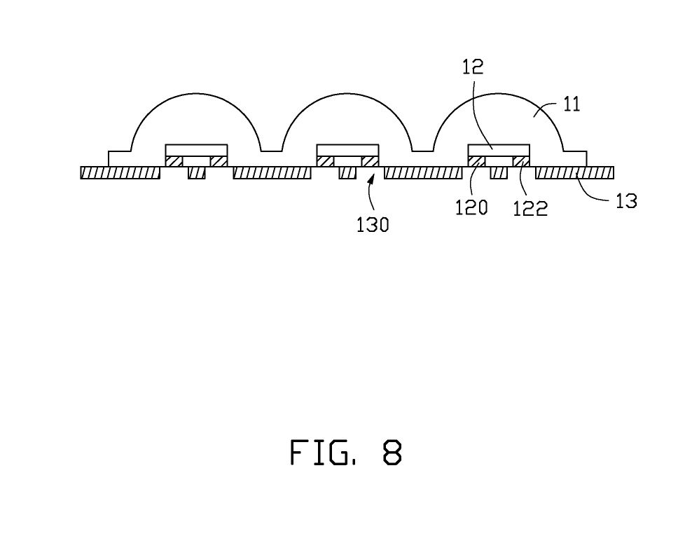

At block 208, referring to FIG. 8, an isolating layer 13 is formed on the bottom surface 112 of the encapsulation 11 except the electrodes 120, 122, thereby defining a plurality of recesses 130. The isolating layer 13 is formed on the exposed surface encapsulation surface portion of the one or more encapsulated light emitting diode dies 12. Each recess 130 is below a corresponding electrode 120/122. Each electrode 120/122 is exposed out of the corresponding recess 130. The isolating layer 13 can be made of epoxy molding compound (EMC) or sheet molding compound (SMC).

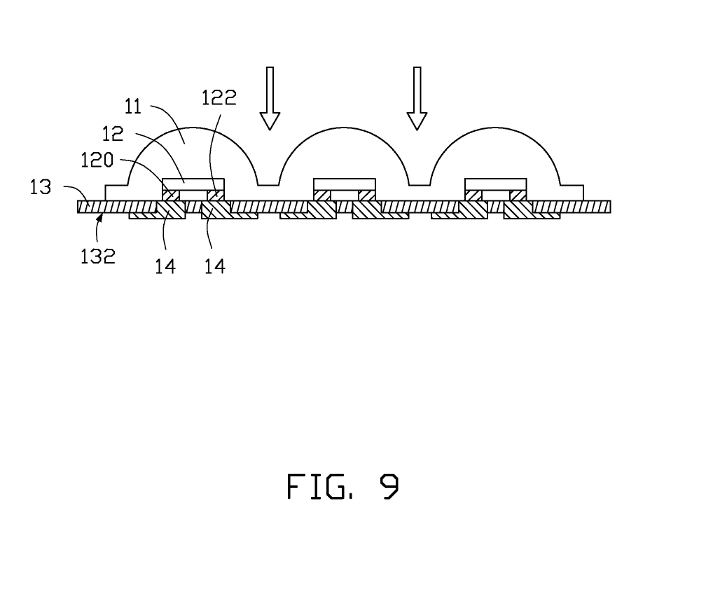

At block 210, referring to FIG. 9, a plurality of leads 14 are formed in the recesses 130 of the isolating layer 13 to connect to the electrodes 120/122. Each lead 14 is formed in a corresponding recess 130 and connected to a corresponding electrode 120/122. Each lead 14 is extended from the corresponding recess 130 of the isolating layer 13 in a direction away from the encapsulation 11 and covers part of a lower surface 132 of the encapsulation 13. The leads 14 can be formed by toping metal material in the recesses 130. And the toping process can be electroplating or spraying.

The method 200 can further include a step of cutting the encapsulation 11 and the isolating layer 13 into several individual pieces to obtain several individual light emitting diode packages 10. Each light emitting diode package 10 includes one light emitting diode die 12 and two leads 14. In this embodiment, the cutting process is performed along an arrowhead illustrated in FIG. 9 on the encapsulation 11 and the isolating layer 13.

The film 20 can be made of an uv film. Accordingly, when the film 20 is needed to be removed, an uv light can be supplied on the uv film to decrease a viscosity of the uv film, thereby separating the uv film from the encapsulation 11.

It is to be further understood that even though numerous characteristics and advantages have been set forth in the foregoing description of embodiments, together with details of the structures and functions of the embodiments, the disclosure is illustrative only; and that changes may be made in detail, according in matters of shape, size, and arrangement of parts within the principles of the disclosure to the full extent indicated by the broad general meaning of the terms in which the appended claims are expressed.

The embodiments shown and described above are only examples. Many details are often found in the art such as the other features of a light emitting diode package. Therefore, many such details are neither shown nor described. Even though numerous characteristics and advantages of the present technology have been set forth in the foregoing description, together with details of the structure and function of the present disclosure, the disclosure is illustrative only, and changes may be made in the detail, especially in matters of shape, size and arrangement of the parts within the principles of the present disclosure up to, and including the full extent established by the broad general meaning of the terms used in the claims. It will therefore be appreciated that the embodiments described above may be modified within the scope of the claims.

What is claimed is:

1. A method of manufacturing a light emitting diode package comprising:
arranging one or more light emitting diode dies on a film, with the electrodes of each of the one or more light emitting diode dies positioned on the film;
encapsulating the one or more light emitting diode dies on the film;
removing the film from the one or more encapsulated light emitting diode dies to expose a surface of the one or more encapsulated light emitting diode dies, the exposed surface including the un-encapsulated electrodes of each of the one or more light emitting diode dies and the exposed surface encapsulation surface portion;
forming an isolating layer on the exposed surface encapsulation surface portion of the one or more encapsulated light emitting diode dies so as to define a plurality of recesses; and
forming a plurality of leads in the plurality of recesses of the one or more encapsulated light emitting diode dies, with each one of the plurality of leads being connected to one of the un-encapsulated electrodes of the one or more light emitting diode dies.

2. The method of manufacturing the light emitting diode package of claim 1, wherein the light emitting diode dies are inverted by flip-chip bonding, thereby attaching the electrodes on the film.

3. The method of manufacturing the light emitting diode package of claim 1, wherein encapsulating material is used for encapsulating the one or more light emitting diode dies on the film, and the encapsulating material is fillight emitting diode on the film by molding.

4. The method of manufacturing the light emitting diode package of claim 1, wherein the electrodes are inserted in the encapsulation with bottoms attached on the film.

5. The method of manufacturing the light emitting diode package of claim 1, wherein each recess is below a corresponding electrode.

6. The method of manufacturing the light emitting diode package of claim 5, wherein each electrode is exposed out of the corresponding recess.

7. The method of manufacturing the light emitting diode package of claim 6, wherein each lead is formed in a corresponding recess and connected to a corresponding electrode.

8. The method of manufacturing the light emitting diode package of claim 6, wherein each lead is extended from the corresponding recess of the isolating layer in a direction away from the encapsulation and covers part of the encapsulation.

9. The method of manufacturing the light emitting diode package of claim 1, wherein the leads is formed by toping metal material in the recesses.

10. The method of manufacturing the light emitting diode package of claim 9, wherein the toping process can be electroplating or spraying.

11. The method of manufacturing the light emitting diode package of claim 9 further comprising cutting the encapsulation and the isolating layer into several individual pieces to obtain several individual light emitting diode packages after the step of forming a plurality of leads in the recesses of the isolating layer to connect to the electrodes.

12. The method of manufacturing the light emitting diode package of claim 1, wherein the film is made of an UV film, and the film is removed by striking in a an uv light.

13. The method for manufacturing the light emitting diode package of claim 1, wherein the isolating layer is not transparent, and is made of epoxy molding compound or sheet molding compound.

14. A light emitting diode package, comprising:
an encapsulation;
an light emitting diode die mounted on a bottom of the encapsulation with two un-encapsulated electrodes on the bottom of the encapsulation;
an isolating layer covering the bottom of the encapsulation without the electrodes, thereby defining two recesses to expose the electrodes; and
two leads each formed in one of the recesses.

15. The light emitting diode package of claim 14, wherein the encapsulation has a bottom surface, and the two electrodes stand on the bottom surface and are exposed out thereof.

16. The light emitting diode package of claim 15, wherein the isolating layer covers the bottom surface of the encapsulation with the electrodes exposed out of the isolating layer.

17. The light emitting diode package of claim 14, wherein the isolating layer comprises a lower surface away from the encapsulation, each lead is extended from one recess of the isolating layer away from the encapsulation and covers the lower surface of the isolating layer.
